(19) United States
(12) Patent Application Publication
(10) Pub. No.: US 2023/0407178 A1
(43) Pub. Date: Dec. 21, 2023

(54) MICROMACHINING PROCESSING AGENT AND MICROMACHINING PROCESSING METHOD

(71) Applicant: STELLA CHEMIFA CORPORATION, Osaka (JP)

(72) Inventors: Kazuya DATE, Osaka (JP); Nodoka NAKATA, Osaka (JP); Rui HASEBE, Osaka (JP); Keiichi NII, Osaka (JP)

(21) Appl. No.: 18/251,334

(22) PCT Filed: Oct. 27, 2021
(86) PCT No.: PCT/JP2021/039712

§ 371 Date: May 1, 2023

(30) Foreign Application Priority Data
Nov. 9, 2020 (JP) 2020-186466

(51) Int. Cl. C09K 13/08; H01L 21/311

(52) U.S. Cl. CPC C09K 13/08; H01L 21/31111

(57) ABSTRACT

A micromachining processing agent and a micromachining processing method capable of selectively micromachining a silicon oxide film when a laminated film including at least a silicon nitride film, a silicon oxide film, and a silicon alloy film is micromachined. The micromachining processing agent is used for micromachining of a laminated film including at least a silicon oxide film, a silicon nitride film, and a silicon alloy film. The micromachining processing agent contains: (a) 0.01 to 50 mass % of hydrogen fluoride; (b) 0.1 to 40 mass % of ammonium fluoride; (c) 0.001 to 10 mass % of a water-soluble polymer; (d) 0.001 to 1 mass % of an organic compound having a carboxyl group; and (e) water as an optional component, in which the water-soluble polymer is at least one selected from a group consisting of acrylic acid, ammonium acrylate, acrylamide, styrenesulfonic acid, ammonium styrenesulfonate, and styrenesulfonic acid ester.

### TECHNICAL FIELD

The present invention relates to a micromachining processing agent and a micromachining processing method used for micromachining including cleaning processing and the like in the production of semiconductor devices, liquid crystal display devices, and micro machine (micro electro mechanical systems, MEMS) devices, and the like, and particularly relates to a micromachining processing agent and a micromachining processing method used for micromachining of a laminated film including at least a silicon nitride film, a silicon oxide film, and a silicon alloy.

### BACKGROUND ART

In the production process of a semiconductor element, it is one of the most important processes to pattern and etch a silicon oxide film, a silicon nitride film, a silicon alloy, a polysilicon film, a metal film, or the like formed on a wafer surface in a desired shape. In wet etching, which is one type of the etching technique, a micromachining processing method capable of selectively etching only a film to be etched is required.

Examples of a method for etching a silicon oxide film in the micromachining processing method include a method using buffered hydrofluoric acid or hydrofluoric acid. However, when the buffered hydrofluoric acid or hydrofluoric acid is used as a micromachining processing agent for a structure on which a silicon nitride film, a silicon oxide film, and a silicon alloy film are formed, the silicon nitride film and the silicon alloy film may be etched at the same time. As a result, it is difficult to pattern the structure in a desired shape.

As a micromachining processing agent capable of solving such a problem and selectively etching only the silicon oxide film with respect to the silicon nitride film, a micromachining processing agent obtained by adding an anionic surfactant such as ammonium lauryl sulfate to hydrofluoric acid is exemplified (see, Patent Literature 1). However, this micromachining processing agent has an extremely large foaming property, and thus is not suitable for use in the production process of a semiconductor element.

In addition, a micromachining processing agent containing at least one of hydrogen fluoride or ammonium fluoride, and a water-soluble polymer can also be exemplified (see, Patent Literature 2). Further, a micromachining processing agent containing at least one of hydrogen fluoride or ammonium fluoride and at least one acid selected from the group consisting of hydrochloric acid, sulfuric acid, and phosphoric acid can also be exemplified (see, Patent Literature 3). However, these micromachining processing agents only suppress micromachining of the silicon nitride film, and for example, when the laminated film includes the silicon alloy film, it is difficult to suppress micromachining of the silicon alloy film.

Incidentally, the semiconductor element used in wet etching with the micromachining processing agent is, for example, a dynamic random access memory (DRAM). The semiconductor element constituting the DRAM includes a memory cell area and a peripheral circuit area. In the memory cell area of the DRAM, a plurality of memory cells are two-dimensionally arranged. Each memory cell includes one transistor and one capacitor. The process node of this DRAM has been miniaturized to near 10 nm, and high integration has been advanced. The high integration of the DRAM is mainly attributable to high integration of the capacitor. Therefore, in order to secure a capacitance value necessary for a stable storage operation while reducing the occupied area of the capacitor, an increase in the capacitor area, thinning of the capacitor insulating film, and introduction of the high dielectric constant film are performed.

As the capacitor insulating film, a silicon oxide film or a silicon nitride film is used in addition to a hafnium oxide film or a zirconia oxide film. In addition, there is a technique of forming, as a stopper film, a silicon nitride film serving as a sacrificial layer of a silicon oxide film in order to form a capacitor. In a case where the silicon nitride film which is the sacrificial layer of the silicon oxide film is removed by wet etching, a conventional etching liquid causes a problem that the silicon nitride film is particularly etched.

In addition, a gate electrode portion is provided in a transistor region of the memory cell of the DRAM. The gate electrode portion includes: a sacrificial layer made of a silicon oxide film; a gate spacer film made of a silicon nitride film; a gate electrode made of polysilicon and tungsten or the like; and a silicon alloy film that reduces contact resistance between the gate electrode and the insulating film and is made of cobalt silicide or the like. When the gate electrode portion is formed, there is a step of removing the silicon oxide film by wet etching. When a conventional etching liquid is used to remove the silicon oxide film, there is a problem that the silicon nitride film and the silicon alloy film are particularly etched.

As a method for solving this problem, for example, a gate spacer oxide material removing composition containing hydrofluoric acid or ammonium fluoride, an organic solvent such as acetone or ethylene glycol, and a chelating agent such as benzotriazole has been proposed (see, Patent Literature 4). However, even with this gate spacer oxide material removing composition, the selective etching of the gate spacer oxide material is insufficient, and further improvement in the accuracy of the selective etching is required.

### CITATION LIST

### Patent Literature

Patent Literature 1: JP-A-2005-328067
Patent Literature 2: JP-A-2012-227558
Patent Literature 3: JP-B-5400528
Patent Literature 4: JP-T-2009-512195

### SUMMARY OF INVENTION

### Technical Problem

The present invention has been made in view of the above problems, and an object thereof is to provide a micromachining processing agent and a micromachining processing method capable of selectively micromachining a silicon oxide film when micromachining a laminated film including at least a silicon nitride film, a silicon oxide film, and a silicon alloy film.

### Solution to Problem

In order to solve the above problems, a micromachining processing agent of the present invention is a micromachining processing agent used for micromachining of a laminated film including at least a silicon oxide film, a silicon nitride film, and a silicon alloy film, the micromachining processing agent containing: (a) hydrogen fluoride in an amount of 0.01 to 50 mass % with respect to a total mass of the micromachining processing agent; (b) ammonium fluoride in an amount of 0.1 to 40 mass % with respect to a total mass of the micromachining processing agent; (c) a water-soluble polymer in an amount of 0.001 to 10 mass % with respect to a total mass of the micromachining processing agent; (d) an organic compound having a carboxyl group in an amount of 0.001 to 1 mass % with respect to a total mass of the micromachining processing agent; and (e) water as an optional component, in which the water-soluble polymer includes a polymer provided by polymerizing at least one monomer component selected from a group consisting of acrylic acid, ammonium acrylate, acrylamide, styrenesulfonic acid, ammonium styrenesulfonate, and styrenesulfonic acid ester, and the silicon oxide film is selectively micromachined in the laminated film.

According to the above configuration, the micromachining processing agent contains hydrogen fluoride in an amount of 0.01 mass % to 50 mass % with respect to the total mass of the micromachining processing agent, and ammonium fluoride in an amount of 0.1 mass % to 40 mass % with respect to the total mass of the micromachining processing agent, whereby good micromachining of the silicon oxide film can be achieved. On the other hand, the micromachining processing agent contains a water-soluble polymer such as acrylic acid in an amount of 0.001 mass % to 10 mass % with respect to the total mass of the micromachining processing agent, whereby micromachining of the silicon nitride film is suppressed, and the micromachining processing agent contains an organic compound having a carboxyl group in an amount of 0.001 mass % to 1 mass % with respect to the total mass of the micromachining processing agent, whereby micromachining of the silicon alloy film is also suppressed. That is, with the micromachining processing agent having the above configuration, in a laminated film including at least a silicon oxide film, a silicon nitride film, and a silicon alloy film, selective micromachining on the silicon oxide film can be favorably performed while micromachining on the silicon nitride film and the silicon alloy film is suppressed.

In the present specification, the term “micromachining” means processing including etching a film to be processed and cleaning a surface. In addition, the term “water-soluble polymer” means a polymer that dissolves in an amount of 1 mass % or more (10 g/L) at normal temperature in a mixed solution containing the component (a), the component (b), the component (d), and the component (e). In the present specification, the term “normal temperature” means a temperature in a range of 5° C. to 35° C.

In the above configuration, the water-soluble polymer is preferably polystyrene sulfonic acid.

In the above configuration, the organic compound having a carboxyl group is preferably at least one selected from a group consisting of a carboxylic acid represented by CₙH₂ₙ₊₁COOH where n represents a natural number in a range of 0 to 9, a perfluoroalkyl carboxylic acid, a carboxylic acid having two or more carboxyl groups, and an amino acid.

Further, in the above configuration, the carboxylic acid represented by CₙH₂ₙ₊₁COOH is preferably hexanoic acid, heptanoic acid, octanoic acid, or nonanoic acid.

In the above configuration, the perfluoroalkyl carboxylic acid is preferably perfluoropentanoic acid.

In order to solve the above problems, a micromachining processing method of the present invention includes, in a laminated film including at least a silicon oxide film, a silicon nitride film, and a silicon alloy film, selectively micromachining the silicon oxide film, using the micromachining processing agent.

According to the above configuration, with the micromachining processing agent, selective micromachining can be favorably performed on the silicon oxide film while suppressing micromachining on the silicon nitride film and the silicon alloy film in a laminated film including at least the silicon oxide film, the silicon nitride film, and the silicon alloy film. As a result, the micromachining processing method having the above configuration can reduce the yield in the production process of a semiconductor element.

In the above configuration, the silicon oxide film is preferably any one of a natural oxide film, a chemical oxide film, a silicon thermal oxide film, a non-doped silicate glass film, a phosphorus-doped silicate glass film, a boron-doped silicate glass film, a phosphorus boron-doped silicate glass film, a tetraethyl orthosilicate (TEOS) film, a fluorine-containing silicon oxide film, a carbon-containing silicon oxide film, a nitrogen-containing silicon oxide film, a spin on glass (SOG) film, or a spin on dielectroric (SOD) film.

In the above configuration, the silicon nitride film is preferably any one of a silicon nitride film, an oxygen-containing silicon nitride film, or a carbon-containing silicon nitride film.

Further, in the above configuration, the silicon alloy film is preferably made of any one of cobalt silicide, nickel silicide, titanium silicide, or tungsten silicide.

### Advantageous Effects of Invention

According to the present invention, only the silicon oxide film can be selectively subjected to micromachining processing while suppressing micromachining of the silicon nitride film and the silicon alloy film in the laminated film including at least the silicon oxide film, the silicon nitride film, and the silicon alloy film. As a result, with the micromachining processing agent and the micromachining processing method using the micromachining processing agent according to the present invention, for example, suitable micromachining in the production of a semiconductor device, a liquid crystal display device, a micromachine device, or the like can be achieved.

### DESCRIPTION OF EMBODIMENTS

### (Micromachining Processing Agent)

An embodiment of the present invention will be described below.

The micromachining processing agent according to the present embodiment contains at least (a) hydrogen fluoride, (b) ammonium fluoride, (c) a water-soluble polymer, (d) an organic compound having a carboxyl group, and (e) water as an optional component.

The content of hydrogen fluoride as the component (a) is in a range of 0.01 mass % to 50 mass %, and preferably in a range of 0.05 mass % to 25 mass %, with respect to the total mass of the micromachining processing agent. When the content of hydrogen fluoride is 0.01 mass % or more, the concentration of hydrogen fluoride can be controlled, thus making it possible to suppress an increase in variation in the etch rate for the silicon oxide film. In addition, when the content of hydrogen fluoride is 25 mass % or less, it is possible to prevent deterioration of the controllability of micromachining such as etching due to excessive increase in the etch rate for the silicon oxide film.

The content of ammonium fluoride as the component (b) is in a range of 0.1 mass % to 40 mass %, and preferably in a range of 1 mass % to 25 mass %, with respect to the total mass of the micromachining processing agent. When the content of ammonium fluoride is 0.1 mass % or more, the concentration of ammonium fluoride can be controlled, thus making it possible to suppress an increase in variation in the etch rate for the silicon oxide film. In addition, when the content of ammonium fluoride is 40 mass % or less, the solubility of ammonium fluoride is prevented from reaching the saturation solubility. As a result, for example, it is possible to prevent a phenomenon that the liquid temperature of the micromachining processing agent is lowered, the solubility of the ammonium fluoride reaches the saturation solubility, and the crystals of the ammonium fluoride deposits in the micromachining processing agent.

In the micromachining processing agent of the present embodiment, inclusion of hydrogen fluoride as the component (a) and ammonium fluoride as the component (b) is to enable the silicon oxide film to be finely processed.

The water-soluble polymer as the component (c) is a polymer of at least one monomer component selected from the group consisting of acrylic acid, ammonium acrylate, acrylic acid ester, acrylamide, styrenesulfonic acid, ammonium styrenesulfonate, and styrenesulfonic acid ester.

Among the polymers of monomer components listed above, a copolymer composed of styrenesulfonic acid and ammonium styrenesulfonate is preferable from the viewpoint of providing a high effect of suppressing micromachining such as etching on a silicon nitride film. The polymerization ratio between styrenesulfonic acid and ammonium styrenesulfonate is preferably in a range of 9.9:0.1 to 5:5. When the polymerization ratio of ammonium styrenesulfonate is larger than the above numerical range, there may be a disadvantage that the solubility is reduced and the copolymer is less likely to be dissolved.

Among the polymers composed of the monomer components listed above, a copolymer composed of ammonium acrylate and methyl acrylate, and polyacrylamide composed of a polymer of acrylamide can further enhance an effect of suppressing micromachining such as etching on a silicon nitride film by combined use with hydrogen fluoride as the component (a) and ammonium fluoride as the component (b). Polystyrene sulfonic acid composed of a polymer of styrenesulfonic acid is preferable from the viewpoint that an effect of suppressing etching on a silicon nitride film is high at a small addition concentration.

The content of the water-soluble polymer as the component (c) is in a range of mass % to 10 mass %, and preferably in a range of 0.1 mass % to 5 mass %, with respect to the total mass of the micromachining processing agent. When the content of the water-soluble polymer is 0.001 mass % or more, an effect of addition of the water-soluble polymer can be maintained, thus making it possible to favorably maintain an effect of suppressing increase in the etch rate for the silicon nitride film. When the content of the water-soluble polymer is 10 mass % or less, an increase in metal impurities in the micromachining processing agent can be suppressed. In addition, an increase in viscosity of the micromachining processing agent is suppressed to prevent a decrease in rinse removal performance of a rinse agent such as ultrapure water for removal of the micromachining processing agent, and thus suitable application of the agent to the production process of a semiconductor device can be achieved.

The weight average molecular weight of the water-soluble polymer is preferably in a range of 1,000 to 1,000,000, and more preferably in a range of 1,000 to 10,000. When the weight average molecular weight of the water-soluble polymer is 1,000 or more, the amount of a stabilizer to be used as a polymerization inhibitor can be suppressed. As a result, it is possible to reduce a possibility that the stabilizer causes metal contamination or the like in the micromachining processing agent. When the weight average molecular weight of the water-soluble polymer is 1,000,000 or less, it is possible to prevent deterioration of the handleability due to increase in the viscosity of the micromachining processing agent. In addition, a deterioration in rinse removal performance of a rinse agent such as ultrapure water for removal of the micromachining processing agent is prevented, and thus suitable application of the agent to the production process of a semiconductor device can be achieved.

When the organic compound having a carboxyl group as the component (d) is contained in the micromachining processing agent, micromachining such as surface etching on the silicon alloy film can be suppressed. Examples of the organic compound having a carboxyl group include at least one selected from the group consisting of a carboxylic acid (fatty acid) represented by CₙH₂ₙ₊₁COOH where n represents a natural number in a range of 0 to 9, a perfluoroalkyl carboxylic acid, a carboxylic acid having two or more carboxyl groups, and an amino acid.

The carboxylic acid represented by CₙC₂ₙ₊₁COOH is not particularly limited, and examples thereof include methanoic acid (formic acid), ethanoic acid (acetic acid), propanoic acid (propionic acid), butanoic acid (butyric acid), pentanoic acid (valeric acid), hexanoic acid (caproic acid), heptanoic acid (enanthic acid), octanoic acid (caprylic acid), nonanoic acid (pelargonic acid), and decanoic acid (capric acid). Among these carboxylic acids, in the present embodiment, hexanoic acid, heptanoic acid, octanoic acid, and nonanoic acid are preferable from the viewpoint of enhancing an effect of suppressing etching on a silicon nitride film.

The perfluoroalkyl carboxylic acid is not particularly limited, and examples thereof include perfluoropentanoic acid, and the like.

The carboxylic acid having two or more carboxyl groups is not particularly limited, and examples thereof include oxalic acid, citric acid, and malonic acid.

The content of the organic compound having a carboxyl group is in a range of 0.001 mass % to 1 mass %, preferably 0.002 mass % to 0.05 mass %, with respect to the total mass of the micromachining processing agent. When the content of the organic compound is 0.001 mass % or more, micromachining such as etching on the silicon alloy film can be favorably suppressed. When the content of the organic compound is 0.1 mass % or less, it is possible to reduce or prevent occurrence of etching defects due to bubbles entering into fine gaps, such as occurrence of etching unevenness due to bubbles adhering to a micromachined (etched) surface, which is caused by deterioration of defoaming properties of the micromachining processing agent.

Depending on the purity of the micromachining surface processing agent, the water-soluble polymer to be added may be purified using distillation, ion exchange resin, ion exchange membrane, electrodialysis, filtration or the like, or may be purified by performing circulating filtration or the like using the micromachining processing agent.

The water as the component (e) is not particularly limited, but pure water, ultrapure water, or the like is preferable.

The content of water as the component (e) is preferably in a range of 0 mass % to 99.888 mass %, and more preferably 40 mass % to 98.848 mass %, with respect to the total mass of the micromachining processing agent.

In the micromachining processing agent of the present embodiment, other additives can be mixed in a range in which the effect thereof is not inhibited. Examples of the additive include hydrogen peroxide and a chelating agent.

Depending on the required purity of the micromachining surface processing agent, the water-soluble polymer and organic compound having a carboxyl group, which are to be added, may be purified using distillation, ion exchange resin, ion exchange membrane, electrodialysis, filtration or the like, or may be purified by performing circulating filtration or the like using the micromachining processing agent.

### (Micromachining Processing Method)

Next, a micromachining processing method using the micromachining processing agent of the present embodiment will be described below.

Hereinafter, a case where wet etching is performed on a laminated film including at least a silicon oxide film, a silicon nitride film, and a silicon alloy film will be described as an example.

The micromachining processing agent of the present embodiment is employed in various wet etching methods. Examples of the wet etching method include a batch method and a single wafer method, and the micromachining processing agent of the present invention can be employed in any method. Examples of the method for bringing the micromachining processing agent into contact with the laminated film include an immersion method and a spray method. Among these contact methods, the immersion method is suitable because the method can reduce or suppress a change in the composition due to evaporation of the micromachining processing agent during the step.

When the micromachining processing agent is used as an etching liquid, the etching temperature (that is, the liquid temperature of the micromachining processing agent) is preferably in a range of 5° C. to 50° C., more preferably in a range of 15° C. to and still more preferably in a range of 20° C. to 30° C. When the etching temperature is 50° C. or lower, evaporation of the micromachining processing agent can be suppressed, thus making it possible to prevent a change in the composition of the micromachining processing agent. In addition, it is possible to prevent the etch rate from being difficult to control due to evaporation of the micromachining processing agent. On the other hand, when the etching temperature is 5° C. or higher, it is possible to suppress crystallization of optional components contained in the micromachining processing agent and to prevent an increase in crystallized particles in the micromachining processing agent due to a decrease in the etch rate. Note that, since the etch rate varies for each film constituting the laminated film depending on the etching temperature, the difference among the etch rates for the silicon oxide film, the silicon nitride film, and the silicon alloy film may also be affected.

In the micromachining processing agent according to the present embodiment, the etch rate for the silicon oxide film at 25° C. is preferably in a range of 1 to 5,000 nm/min (10 to 50,000 Å/min), more preferably in a range of 1 to 1,000 nm/min (10 to Å/min). When the etch rate is 1 nm/min or more, it is possible to prevent the time of micromachining processing such as etching from becoming long and to thereby suppress a decrease in processing efficiency. In addition, when the etch rate is 5,000 nm/min or less, it is possible to prevent deterioration in the controllability of the film thickness after micromachining and increased roughness of the substrate surface (surface opposite to the surface on which the silicon oxide film or the like is formed), and to improve the yield.

Here, the silicon oxide film is not particularly limited as long as it contains silicon (Si) and oxygen (O). Specific examples of the silicon oxide film include a natural oxide film, a chemical oxide film, a silicon thermal oxide film, a non-doped silicate glass film, a phosphorus-doped silicate glass film, a boron-doped silicate glass film, a phosphorus boron-doped silicate glass film, a tetraethyl orthosilicate (TEOS) film, a fluorine-containing silicon oxide film, a carbon-containing silicon oxide film, a nitrogen-containing silicon oxide film, a spin on glass (SOG) film, and a spin on dielectric (SOD) film.

The natural oxide film in the silicon oxide film is a silicon oxide film formed on silicon during exposure to the atmosphere at room temperature. The chemical oxide film is, for example, a film formed on silicon during cleaning with sulfuric acid/hydrogen peroxide water. The silicon thermal oxide film is a film formed at a high temperature of 800 to 1,000° C. by supplying water vapor or oxygen gas. In the non-doped silicate glass film, the phosphorus-doped silicate glass film, the boron-doped silicate glass film, the phosphorus boron-doped silicate glass film, the TEOS film, the fluorine-containing silicon oxide film, the carbon-containing silicon oxide film, and the nitrogen-containing silicon oxide film, a film can be formed by supplying a raw material gas such as silane gas, and depositing a silicon oxide film by chemical vapor deposition (CVD). The SOG film and the SOD film can be formed by a coating method such as a method using a spin coater.

The silicon nitride film is not particularly limited, and examples thereof include a silicon nitride film, an oxygen-containing silicon nitride film, and a carbon-containing silicon nitride film.

The method for forming the silicon nitride film is not particularly limited, and examples thereof include CVD using silane gas, ammonia gas, or other raw material gases.

The silicon alloy film is not particularly limited, and examples thereof include a film made of cobalt silicide, nickel silicide, titanium silicide, tungsten silicide, or the like.

The silicon alloy film can be formed by forming a film of the metal compound of cobalt, nickel, titanium, or tungsten on the surface of a silicon portion by CVD or physical vapor deposition (PVD) and performing an annealing treatment.

Examples of the CVD include film formation methods such as plasma enhanced chemical vapor deposition (PECVD), atomic layer deposition (ALD), metal organic chemical vapor deposition (MOCVD), catalytic chemical vapor deposition (Cat-CVD), thermal CVD, and epitaxial CVD. Examples of the PVD include film forming methods such as vacuum deposition, ion plating, ion beam deposition, and sputtering.

### EXAMPLES

Suitable Examples of the present invention will be described in detail below. However, materials or mixing amounts mentioned in these Examples do not purport to limit the scope of the present invention only to these unless there is a definitive description.

(Etch rate for silicon oxide film and silicon nitride film)

The film thicknesses of the silicon oxide film and the silicon nitride film before and after etching were measured with an optical film thickness measuring device (Nanospec M6100, manufactured by Nanometrics Japan Ltd.), and a change in the film thickness due to etching was measured. The measurement was repeatedly performed at three different etching times, and the etch rate was calculated.

### (Etch Rate for Silicon Alloy Film)

The film thickness of the silicon alloy film before and after etching was measured by spectroscopic ellipsometry (UVISEL/M200-FUV-AGMS, manufactured by HORIBA JOBIN YVON S.A.S.), and a change in the film thickness due to etching was measured. The measurement was repeatedly performed at three different etching times, and the etch rate was calculated.

### Example 1

First, 0.2 parts by mass of hydrofluoric acid (high purity grade for semiconductors, manufactured by Stella Chemifa Corporation, concentration: 50 mass %), 12.5 parts by mass of ammonium fluoride (high purity grade for semiconductors, manufactured by Stella Chemifa Corporation, concentration: 40 mass %), and 87.3 parts by mass of ultrapure water were mixed.

Next, 0.01 parts by mass of polystyrene sulfonic acid (concentration: 17 mass %, weight average molecular weight: 75,000) as a water-soluble polymer and 0.01 parts by mass of heptanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride as the component (a), 5.0 mass % of ammonium fluoride as the component (b), 0.002 mass % of polystyrene sulfonic acid as the component (c), and 0.01 mass % of heptanoic acid as the component (d) was prepared.

### Example 2

First, a mixed solution containing hydrofluoric acid, ammonium fluoride, and ultrapure water was prepared in the same manner as in Example 1.

Next, 0.01 parts by mass of polystyrene sulfonic acid (concentration: 17 mass %, weight average molecular weight: 75,000) as a water-soluble polymer and 0.01 parts by mass of octanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride as the component (a), 5.0 mass % of ammonium fluoride as the component (b), mass % of polystyrene sulfonic acid as the component (c), and 0.01 mass % of octanoic acid as the component (d) was prepared.

### Example 3

First, a mixed solution containing hydrofluoric acid, ammonium fluoride, and ultrapure water was prepared in the same manner as in Example 1.

Next, 0.01 parts by mass of polystyrene sulfonic acid (concentration: 17 mass %, weight average molecular weight: 75,000) as a water-soluble polymer and parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride as the component (a), 5.0 mass % of ammonium fluoride as the component (b), 0.002 mass % of polystyrene sulfonic acid as the component (c), and mass % of nonanoic acid as the component (d) was prepared.

### Example 4

First, 2.0 parts by mass of hydrofluoric acid (high purity grade for semiconductors, manufactured by Stella Chemifa Corporation, concentration: 50 mass %), 25.0 parts by mass of ammonium fluoride (high purity grade for semiconductors, manufactured by Stella Chemifa Corporation, concentration: 40 mass %), and 73.0 parts by mass of ultrapure water were mixed.

Next, 0.01 parts by mass of polystyrene sulfonic acid (concentration: 17 mass %, weight average molecular weight: 75,000) as a water-soluble polymer and 0.01 parts by mass of heptanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 1.0 mass % of hydrogen fluoride as the component (a), 10.0 mass % of ammonium fluoride as the component (b), 0.002 mass % of polystyrene sulfonic acid as the component (c), and mass % of heptanoic acid as the component (d) was prepared.

### Example 5

First, a mixed solution containing hydrofluoric acid, ammonium fluoride, and ultrapure water was prepared in the same manner as in Example 4.

Next, 0.01 parts by mass of polystyrene sulfonic acid (concentration: 17 mass %, weight average molecular weight: 75,000) as a water-soluble polymer and 0.01 parts by mass of octanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 1.0 mass % of hydrogen fluoride as the component (a), 10.0 mass % of ammonium fluoride as the component (b), mass % of polystyrene sulfonic acid as the component (c), and 0.01 mass % of octanoic acid as the component (d) was prepared.

### Example 6

First, a mixed solution containing hydrofluoric acid, ammonium fluoride, and ultrapure water was prepared in the same manner as in Example 4.

Next, 0.01 parts by mass of polystyrene sulfonic acid (concentration: 17 mass %, weight average molecular weight: 75,000) as a water-soluble polymer and parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 1.0 mass % of hydrogen fluoride as the component (a), 10.0 mass % of ammonium fluoride as the component (b), 0.002 mass % of polystyrene sulfonic acid as the component (c), and mass % of nonanoic acid as the component (d) was prepared.

### Example 7

First, 8.0 parts by mass of hydrofluoric acid (high purity grade for semiconductors, manufactured by Stella Chemifa Corporation, concentration: 50 mass %), 50.0 parts by mass of ammonium fluoride (high purity grade for semiconductors, manufactured by Stella Chemifa Corporation, concentration: 40 mass %), and 42.0 parts by mass of ultrapure water were mixed.

Next, 0.01 parts by mass of polystyrene sulfonic acid (concentration: 17 mass %, weight average molecular weight: 75,000) as a water-soluble polymer and 0.01 parts by mass of hexanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and mass % of hexanoic acid as the component (d) was prepared.

### Example 8

First, a mixed solution containing hydrofluoric acid, ammonium fluoride, and ultrapure water was prepared in the same manner as in Example 7.

Next, 0.01 parts by mass of polystyrene sulfonic acid (concentration: 17 mass %, weight average molecular weight: 75,000) as a water-soluble polymer and parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and mass % of nonanoic acid as the component (d) was prepared.

### Example 9

First, a mixed solution containing hydrofluoric acid, ammonium fluoride, and ultrapure water was prepared in the same manner as in Example 7.

Next, 0.01 parts by mass of polystyrene sulfonic acid (concentration: 17 mass %, weight average molecular weight: 75,000) as a water-soluble polymer and parts by mass of perfluoropentanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and mass % of perfluoropentanoic acid as the component (d) was prepared.

### Example 10

First, a mixed solution containing hydrofluoric acid, ammonium fluoride, and ultrapure water was prepared in the same manner as in Example 7.

Next, 0.006 parts by mass of polystyrene sulfonic acid (concentration: 17 mass %, weight average molecular weight: 200,000) as a water-soluble polymer and parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.001 mass % of polystyrene sulfonic acid as the component (c), and mass % of nonanoic acid as the component (d) was prepared.

### Example 11

First, 8.0 parts by mass of hydrofluoric acid (high purity grade for semiconductors, manufactured by Stella Chemifa Corporation, concentration: 50 mass %), 50.0 parts by mass of ammonium fluoride (high purity grade for semiconductors, manufactured by Stella Chemifa Corporation, concentration: 40 mass %), and 36.0 parts by mass of ultrapure water were mixed.

Next, 6 parts by mass of polyacrylamide (concentration: 50 mass %, weight average molecular weight: 10,000) as a water-soluble polymer and 0.002 parts by mass of nonanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 3.0 mass % of polyacrylamide as the component (c), and 0.002 mass % of nonanoic acid as the component (d) was prepared.

### Example 12

First, 8.0 parts by mass of hydrofluoric acid (high purity grade for semiconductors, manufactured by Stella Chemifa Corporation, concentration: 50 mass %), 50.0 parts by mass of ammonium fluoride (high purity grade for semiconductors, manufactured by Stella Chemifa Corporation, concentration: 40 mass %), and 40.0 parts by mass of ultrapure water were mixed.

Next, 2 parts by mass of polyacrylamide (concentration: 50 mass %, weight average molecular weight: 1,500) as a water-soluble polymer and 0.002 parts by mass of nonanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 1.0 mass % of polyacrylamide as the component (c), and 0.002 mass % of nonanoic acid as the component (d) was prepared.

### Example 13

First, a mixed solution containing hydrofluoric acid, ammonium fluoride, and ultrapure water was prepared in the same manner as in Example 12.

Next, 2 parts by mass of copolymer of ammonium acrylate and methylamide acrylate (concentration: 50 mass %, weight average molecular weight: 8,000) as a water-soluble polymer and 0.002 parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 1.0 mass % of copolymer of ammonium acrylate and methylamide acrylate as the component (c), and 0.002 mass % of nonanoic acid as the component (d) was prepared.

### Example 14

First, 8.0 parts by mass of hydrofluoric acid (high purity grade for semiconductors, manufactured by Stella Chemifa Corporation, concentration: 50 mass %), 50.0 parts by mass of ammonium fluoride (high purity grade for semiconductors, manufactured by Stella Chemifa Corporation, concentration: 40 mass %), and 41.0 parts by mass of ultrapure water were mixed.

Next, 0.01 parts by mass of polystyrene sulfonic acid (concentration: 17 mass %, weight average molecular weight: 75,000) as a water-soluble polymer and 1 part by mass of propionic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and 1.0 mass % of propionic acid as the component (d) was prepared.

### Example 15

First, a mixed solution containing hydrofluoric acid, ammonium fluoride, and ultrapure water was prepared in the same manner as in Example 7.

Next, 0.01 parts by mass of polystyrene sulfonic acid (concentration: 17 mass %, weight average molecular weight: 75,000) as a water-soluble polymer, and 0.001 parts by mass of octanoic acid (concentration: 99.9 mass %) and 0.001 parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and 0.001 mass % of octanoic acid and 0.001 mass % of nonanoic acid as the component (d) was prepared.

### Example 16

First, a mixed solution containing hydrofluoric acid, ammonium fluoride, and ultrapure water was prepared in the same manner as in Example 7.

Next, 0.01 parts by mass of polystyrene sulfonic acid (concentration: 17 mass %, weight average molecular weight: 75,000) as a water-soluble polymer and 0.02 parts by mass of malic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), mass % of polystyrene sulfonic acid as the component (c), and 0.02 mass % of malic acid as the component (d) was prepared.

### Example 17

First, a mixed solution containing hydrofluoric acid, ammonium fluoride, and ultrapure water was prepared in the same manner as in Example 7.

Next, 0.01 parts by mass of polystyrene sulfonic acid (concentration: 17 mass %, weight average molecular weight: 75,000) as a water-soluble polymer and 0.02 parts by mass of aspartic acid (concentration: 99.9 mass %) as an organic compound having an amino group and a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride as the component (a), 20.0 mass % of ammonium fluoride as the component (b), 0.002 mass % of polystyrene sulfonic acid as the component (c), and mass % of aspartic acid as the component (d) was prepared.

### Example 18

First, 14.0 parts by mass of hydrofluoric acid (high purity grade for semiconductors, manufactured by Stella Chemifa Corporation, concentration: 50 mass %), 57.5 parts by mass of ammonium fluoride (high purity grade for semiconductors, manufactured by Stella Chemifa Corporation, concentration: 40 mass %), and 28.5 parts by mass of ultrapure water were mixed.

Next, 0.01 parts by mass of polystyrene sulfonic acid (concentration: 17 mass %, weight average molecular weight: 75,000) as a water-soluble polymer and 0.01 part by mass of octanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride as the component (a), 23.0 mass % of ammonium fluoride as the component (b), 0.002 mass % of polystyrene sulfonic acid as the component (c), and mass % of octanoic acid as the component (d) was prepared.

### Example 19

First, a mixed solution containing hydrofluoric acid, ammonium fluoride, and ultrapure water was prepared in the same manner as in Example 18.

Next, 0.01 parts by mass of polystyrene sulfonic acid (concentration: 17 mass %, weight average molecular weight: 75,000) as a water-soluble polymer and parts by mass of nonanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride as the component (a), 23.0 mass % of ammonium fluoride as the component (b), 0.002 mass % of polystyrene sulfonic acid as the component (c), and mass % of nonanoic acid as the component (d) was prepared.

### Example 20

First, a mixed solution containing hydrofluoric acid, ammonium fluoride, and ultrapure water was prepared in the same manner as in Example 18.

Next, 0.01 parts by mass of polystyrene sulfonic acid (concentration: 17 mass %, weight average molecular weight: 75,000) as a water-soluble polymer and parts by mass of perfluoropentanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride as the component (a), 23.0 mass % of ammonium fluoride as the component (b), 0.002 mass % of polystyrene sulfonic acid as the component (c), and mass % of perfluoropentanoic acid as the component (d) was prepared.

### Example 21

First, 14.0 parts by mass of hydrofluoric acid (high purity grade for semiconductors, manufactured by Stella Chemifa Corporation, concentration: 50 mass %), 57.5 parts by mass of ammonium fluoride (high purity grade for semiconductors, manufactured by Stella Chemifa Corporation, concentration: 40 mass %), and 28.5 parts by mass of ultrapure water were mixed.

Next, 0.01 parts by mass of polystyrene sulfonic acid (concentration: 17 mass %, weight average molecular weight: 75,000) as a water-soluble polymer and 0.01 part by mass of hexanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride as the component (a), 23.0 mass % of ammonium fluoride as the component (b), 0.002 mass % of polystyrene sulfonic acid as the component (c), and mass % of hexanoic acid as the component (d) was prepared.

### Example 22

First, a mixed solution containing hydrofluoric acid, ammonium fluoride, and ultrapure water was prepared in the same manner as in Example 21.

Next, 0.01 parts by mass of polystyrene sulfonic acid (concentration: 17 mass %, weight average molecular weight: 75,000) as a water-soluble polymer and parts by mass of perfluoropentanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride as the component (a), 23.0 mass % of ammonium fluoride as the component (b), 0.002 mass % of polystyrene sulfonic acid as the component (c), and mass % of perfluoropentanoic acid as the component (d) was prepared.

### Example 23

First, 50.0 parts by mass of hydrofluoric acid (high purity grade for semiconductors, manufactured by Stella Chemifa Corporation, concentration: 50 mass %), 47.5 parts by mass of ammonium fluoride (high purity grade for semiconductors, manufactured by Stella Chemifa Corporation, concentration: 40 mass %), and 2.5 parts by mass of ultrapure water were mixed.

Next, 0.01 parts by mass of polystyrene sulfonic acid (concentration: 17 mass %, weight average molecular weight: 75,000) as a water-soluble polymer and 0.01 part by mass of heptanoic acid (concentration: 99.9 mass %) as an organic compound having a carboxyl group were added to this mixed solution, and the resulting mixed solution was stirred and mixed. The temperature of the mixed liquid was adjusted so that the liquid temperature was 25° C., and the mixed liquid was left for several hours. As a result, an etching liquid (micromachining processing agent) containing 25.0 mass % of hydrogen fluoride as the component (a), 19.0 mass % of ammonium fluoride as the component (b), 0.002 mass % of polystyrene sulfonic acid as the component (c), and 0.01 mass % of heptanoic acid as the component (d) was prepared.

### Example 24

First, a mixed solution containing hydrofluoric acid, ammonium fluoride, and ultrapure water was prepared in the same manner as in Example 23.

Next, 0.01 parts by mass of polystyrene sulfonic acid (concentration: 17 mass %, weight average molecular weight: 75,000) as a water-soluble polymer and parts by mass of octanoic acid (concentration: 99.9 mass %) as an organic compound having a carboxyl group were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 25.0 mass % of hydrogen fluoride as the component (a), 19.0 mass % of ammonium fluoride as the component (b), 0.002 mass % of polystyrene sulfonic acid as the component (c), and mass % of octanoic acid as the component (d) was prepared.

### Comparative Example 1

0.2 parts by mass of hydrofluoric acid (high purity grade for semiconductors, manufactured by Stella Chemifa Corporation, concentration: 50 mass %), 12.5 parts by mass of ammonium fluoride (high purity grade for semiconductors, manufactured by Stella Chemifa Corporation, concentration: 40 mass %), and 87.3 parts by mass of ultrapure water were mixed. As a result, an etching liquid (micromachining processing agent) containing 0.1 mass % of hydrogen fluoride and 5.0 mass % of ammonium fluoride was prepared.

### Comparative Example 2

First, a mixed solution containing hydrofluoric acid, ammonium fluoride, and ultrapure water was prepared in the same manner as in Comparative Example 1.

Next, 0.01 parts by mass of polystyrene sulfonic acid (concentration: 17 mass %, weight average molecular weight: 75,000) as a water-soluble polymer was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride, 5.0 mass % of ammonium fluoride, and 0.002 mass % of polystyrene sulfonic acid was prepared.

### Comparative Example 3

First, a mixed solution containing hydrofluoric acid, ammonium fluoride, and ultrapure water was prepared in the same manner as in Comparative Example 1.

Next, 0.01 parts by mass of polystyrene sulfonic acid (concentration: 17 mass %, weight average molecular weight: 75,000) as a water-soluble polymer and 0.01 parts by mass of polyoxyethylene isodecyl ether were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride, 5.0 mass % of ammonium fluoride, 0.002 mass % of polystyrene sulfonic acid, and 0.01 mass % of polyoxyethylene isodecyl ether was prepared.

### Comparative Example 4

2.0 parts by mass of hydrofluoric acid (high purity grade for semiconductors, manufactured by Stella Chemifa Corporation, concentration: 50 mass %), 25.0 parts by mass of ammonium fluoride (high purity grade for semiconductors, manufactured by Stella Chemifa Corporation, concentration: 40 mass %), and 73.0 parts by mass of ultrapure water were mixed. As a result, an etching liquid (micromachining processing agent) containing 1.0 mass % of hydrogen fluoride and 10.0 mass % of ammonium fluoride was prepared.

### Comparative Example 5

First, a mixed solution containing hydrofluoric acid, ammonium fluoride, and ultrapure water was prepared in the same manner as in Comparative Example 4.

Next, 0.01 parts by mass of polystyrene sulfonic acid (concentration: 17 mass %, weight average molecular weight: 75,000) as a water-soluble polymer was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 0.1 mass % of hydrogen fluoride, 5.0 mass % of ammonium fluoride, and 0.002 mass % of polystyrene sulfonic acid was prepared.

### Comparative Example 6

First, a mixed solution containing hydrofluoric acid, ammonium fluoride, and ultrapure water was prepared in the same manner as in Comparative Example 4.

Next, 0.01 parts by mass of polystyrene sulfonic acid (concentration: 17 mass %, weight average molecular weight: 75,000) as a water-soluble polymer and 0.01 parts by mass of nonylamine were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 1.0 mass % of hydrogen fluoride, 10.0 mass % of ammonium fluoride, 0.002 mass % of polystyrene sulfonic acid, and 0.01 mass % of nonylamine was prepared.

### Comparative Example 7

8.0 parts by mass of hydrofluoric acid (high purity grade for semiconductors, manufactured by Stella Chemifa Corporation, concentration: 50 mass %), 50.0 parts by mass of ammonium fluoride (high purity grade for semiconductors, manufactured by Stella Chemifa Corporation, concentration: 40 mass %), and 42.0 parts by mass of ultrapure water were mixed. As a result, an etching liquid (micromachining processing agent) containing 4.0 mass % of hydrogen fluoride and 20.0 mass % of ammonium fluoride was prepared.

### Comparative Example 8

First, a mixed solution containing hydrofluoric acid, ammonium fluoride, and ultrapure water was prepared in the same manner as in Comparative Example 7.

Next, 0.01 parts by mass of polystyrene sulfonic acid (concentration: 17 mass %, weight average molecular weight: 75,000) as a water-soluble polymer was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride, 20.0 mass % of ammonium fluoride, and 0.002 mass % of polystyrene sulfonic acid was prepared.

### Comparative Example 9

First, a mixed solution containing hydrofluoric acid, ammonium fluoride, and ultrapure water was prepared in the same manner as in Comparative Example 7.

Next, 0.01 parts by mass of polystyrene sulfonic acid (concentration: 17 mass %, weight average molecular weight: 75,000) as a water-soluble polymer and 0.01 parts by mass of decyl alcohol (concentration: 99.9 mass %) as a fatty acid alcohol were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 4.0 mass % of hydrogen fluoride, 20.0 mass % of ammonium fluoride, 0.002 mass % of polystyrene sulfonic acid and 0.01 mass % of decyl alcohol was prepared.

### Comparative Example 10

14.0 parts by mass of hydrofluoric acid (high purity grade for semiconductors, manufactured by Stella Chemifa Corporation, concentration: 50 mass %), 57.5 parts by mass of ammonium fluoride (high purity grade for semiconductors, manufactured by Stella Chemifa Corporation, concentration: 40 mass %), and 28.5 parts by mass of ultrapure water were mixed. As a result, an etching liquid (micromachining processing agent) containing 7.0 mass % of hydrogen fluoride and 23.0 mass % of ammonium fluoride was prepared.

### Comparative Example 11

First, a mixed solution containing hydrofluoric acid, ammonium fluoride, and ultrapure water was prepared in the same manner as in Comparative Example 10.

Next, 0.01 parts by mass of polystyrene sulfonic acid (concentration: 17 mass %, weight average molecular weight: 75,000) as a water-soluble polymer was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride, 23.0 mass % of ammonium fluoride and 0.002 mass % of polystyrene sulfonic acid was prepared.

### Comparative Example 12

First, a mixed solution containing hydrofluoric acid, ammonium fluoride, and ultrapure water was prepared in the same manner as in Comparative Example 10.

Next, 0.01 parts by mass of polystyrene sulfonic acid (concentration: 17 mass %, weight average molecular weight: 75,000) as a water-soluble polymer and 0.01 parts by mass of sodium monododecyl phosphate (concentration: 99.9 mass %) were added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 7.0 mass % of hydrogen fluoride, 23.0 mass % of ammonium fluoride, 0.002 mass % of polystyrene sulfonic acid, and 0.01 mass % of sodium monododecyl phosphate was prepared.

### Comparative Example 13

50.0 parts by mass of hydrofluoric acid (high purity grade for semiconductors, manufactured by Stella Chemifa Corporation, concentration: 50 mass %), 47.5 parts by mass of ammonium fluoride (high purity grade for semiconductors, manufactured by Stella Chemifa Corporation, concentration: 40 mass %), and 2.5 parts by mass of ultrapure water were mixed. As a result, an etching liquid (micromachining processing agent) containing 25.0 mass % of hydrogen fluoride and 19.0 mass % of ammonium fluoride was prepared.

### Comparative Example 14

First, a mixed solution containing hydrofluoric acid, ammonium fluoride, and ultrapure water was prepared in the same manner as in Comparative Example 13.

Next, 0.01 parts by mass of polystyrene sulfonic acid (concentration: 17 mass %, weight average molecular weight: 75,000) as a water-soluble polymer was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 25.0 mass % of hydrogen fluoride, 19.0 mass % of ammonium fluoride, and 0.002 mass % of polystyrene sulfonic acid was prepared.

### Comparative Example 15

First, a mixed solution containing hydrofluoric acid, ammonium fluoride, and ultrapure water was prepared in the same manner as in Comparative Example 13.

Next, 0.01 parts by mass of polystyrene sulfonic acid (concentration: 17 mass %, weight average molecular weight: 75,000) as a water-soluble polymer and 0.01 parts by mass of dodecyl alcohol (concentration: 99.9 mass %) was added to this mixed solution, and the mixture was stirred and mixed. The temperature of the mixed liquid was adjusted so that the liquid temperature was 25° C., and the mixed liquid was left for several hours. As a result, an etching liquid (micromachining processing agent) containing 25.0 mass % of hydrogen fluoride, 19.0 mass % of ammonium fluoride, 0.002 mass % of polystyrene sulfonic acid, and 0.01 mass % of dodecyl alcohol was prepared.

### (Evaluation of Selectivity of Etch Rate)

The etch rates for the silicon oxide film, the silicon nitride film, and the cobalt silicide film as a silicon alloy film were measured using etching liquids according to Examples 1 to 24 and Comparative Examples 1 to 15.

Next, the selectivity of the etch rate (silicon oxide film/silicon nitride film, and silicon oxide film/cobalt silicide film) was calculated and evaluated. The results are shown in Tables 1 and 2.

TABLE 1

| | Component (a) | Component (b) | Component (c) | | | | |
|---|---|---|---|---|---|---|---|
| | Hydrogen | Ammonium | | Average | | Component (d) | |
| | fluoride | fluoride | | molecular | Content | | Content |
| | (mass %) | (mass %) | Type | weight | (mass %) | Type | (mass %) |
| Example | 0.1 | 5.0 | Polystyrene | 75,000 | 0.002 | Heptanoic acid | 0.01 |
| 1 | | | sulfonic acid | | | | |
| Example | 0.1 | 5.0 | Polystyrene | 75,000 | 0.002 | Octanoic acid | 0.01 |
| 2 | | | sulfonic acid | | | | |
| Example | 0.1 | 5.0 | Polystyrene | 75,000 | 0.002 | Nonanoic acid | 0.002 |
| 3 | | | sulfonic acid | | | | |
| Example | 1.0 | 10.0 | Polystyrene | 75,000 | 0.002 | Heptanoic acid | 0.01 |
| 4 | | | sulfonic acid | | | | |
| Example | 1.0 | 10.0 | Polystyrene | 75,000 | 0.002 | Octanoic acid | 0.01 |
| 5 | | | sulfonic acid | | | | |
| Example | 1.0 | 10.0 | Polystyrene | 75,000 | 0.002 | Nonanoic acid | 0.002 |
| 6 | | | sulfonic acid | | | | |
| Example | 4.0 | 20.0 | Polystyrene | 75,000 | 0.002 | Hexanoic acid | 0.01 |
| 7 | | | sulfonic acid | | | | |
| Example | 4.0 | 20.0 | Polystyrene | 75,000 | 0.002 | Nonanoic acid | 0.002 |
| 8 | | | sulfonic acid | | | | |
| Example | 4.0 | 20.0 | Polystyrene | 75,000 | 0.002 | Perfluoro- | 0.005 |
| 9 | | | sulfonic acid | | | pentanoic acid | |
| Example | 4.0 | 20.0 | Polystyrene | 200,000 | 0.001 | Nonanoic acid | 0.002 |
| 10 | | | sulfonic acid | | | | |
| Example | 4.0 | 20.0 | Polyacrylamide | 10,000 | 3.0 | Nonanoic acid | 0.002 |
| 11 | | | | | | | |
| Example | 4.0 | 20.0 | Polyacrylamide | 1,500 | 1.0 | Nonanoic acid | 0.002 |
| 12 | | | | | | | |
| Example | 4.0 | 20.0 | Copolymer of | 8,000 | 1.0 | Nonanoic acid | 0.002 |
| 13 | | | ammonium | | | | |
| | | | acrylate and | | | | |
| | | | methylamide | | | | |
| | | | acrylate | | | | |
| Example | 4.0 | 20.0 | Polystyrene | 75,000 | 0.002 | Propionic acid | 1.0 |
| 14 | | | sulfonic acid | | | | |
| Example | 4.0 | 20.0 | Polystyrene | 75,000 | 0.002 | Octanoic | 0.001/0.001 |
| 15 | | | sulfonic acid | | | acid/nonanoic acid | |
| Example | 4.0 | 20.0 | Polystyrene | 75,000 | 0.002 | Malic acid | 0.02 |
| 16 | | | sulfonic acid | | | | |
| Example | 4.0 | 20.0 | Polystyrene | 75,000 | 0.002 | Aspartic acid | 0.02 |
| 17 | | | sulfonic acid | | | | |
| Example | 7.0 | 23.0 | Polystyrene | 75,000 | 0.002 | Octanoic acid | 0.01 |
| 18 | | | sulfonic acid | | | | |
| Example | 7.0 | 23.0 | Polystyrene | 75,000 | 0.002 | Nonanoic acid | 0.002 |
| 19 | | | sulfonic acid | | | | |
| Example | 7.0 | 23.0 | Polystyrene | 75,000 | 0.002 | Perfluoro- | 0.005 |
| 20 | | | sulfonic acid | | | pentanoic acid | |
| Example | 7.0 | 23.0 | Polystyrene | 75,000 | 0.002 | Hexanoic acid | 0.01 |
| 21 | | | sulfonic acid | | | | |
| Example | 7.0 | 23.0 | Polystyrene | 75,000 | 0.002 | Perfluoro- | 0.005 |
| 22 | | | sulfonic acid | | | pentanoic acid | |
| Example | 25.0 | 19.0 | Polystyrene | 75,000 | 0.002 | Heptanoic acid | 0.01 |
| 23 | | | sulfonic acid | | | | |
| Example | 25.0 | 19.0 | Polystyrene | 75,000 | 0.002 | Octanoic acid | 0.01 |
| 24 | | | sulfonic acid | | | | |

| | | | | | Selectivity | Selectivity |
|---|---|---|---|---|---|---|
| | | | | | of etch | of etch |
| | | | | | rate | rate |
| | | Etch rate | | | (silicon | (silicon |
| | Component (e) | Silicon | Silicon | Cobalt | oxide | oxide |
| | Ultrapure | oxide | nitride | silicide | film/silicon | film/cobalt |
| | water | film | film | film | nitride | silicide |
| | (mass %) | (nm/min) | (nm/min) | (nm/min) | film) | film) |
| Example | 94.888 | 13.6 | 0.04 | 0.02 | 340 | 680 |
| 1 | | | | | | |
| Example | 94.888 | 14.9 | 0.04 | 0.02 | 373 | 745 |
| 2 | | | | | | |
| Example | 94.896 | 14.0 | 0.05 | <0.01 | 280 | >1,400 |
| 3 | | | | | | |
| Example | 88.988 | 108.7 | 0.24 | 0.26 | 453 | 418 |
| 4 | | | | | | |
| Example | 88.988 | 109.2 | 0.22 | 0.21 | 496 | 520 |
| 5 | | | | | | |
| Example | 88.996 | 109.4 | 0.22 | <0.01 | 497 | >10,940 |
| 6 | | | | | | |
| Example | 75.988 | 292.7 | 0.65 | 0.63 | 450 | 465 |
| 7 | | | | | | |
| Example | 75.996 | 285.3 | 0.64 | 0.02 | 446 | 14,265 |
| 8 | | | | | | |
| Example | 75.993 | 284.3 | 0.64 | 0.69 | 444 | 412 |
| 9 | | | | | | |
| Example | 75.997 | 290.6 | 0.64 | 0.02 | 454 | 14,530 |
| 10 | | | | | | |
| Example | 72.998 | 291.6 | 0.63 | 0.02 | 463 | 14,580 |
| 11 | | | | | | |
| Example | 74.998 | 286.3 | 0.64 | 0.02 | 447 | 14,315 |
| 12 | | | | | | |
| Example | 74.998 | 290.8 | 0.65 | 0.02 | 447 | 14,540 |
| 13 | | | | | | |
| Example | 74.998 | 291.1 | 0.63 | 0.67 | 462 | 462 |
| 14 | | | | | | |
| Example | 75.996 | 286.4 | 0.64 | 0.02 | 448 | 14,320 |
| 15 | | | | | | |
| Example | 75.978 | 283.1 | 0.68 | 1.6 | 416 | 177 |
| 16 | | | | | | |
| Example | 75.978 | 284.3 | 0.68 | 1.4 | 418 | 203 |
| 17 | | | | | | |
| Example | 69.988 | 514.3 | 0.91 | 0.45 | 565 | 1,143 |
| 18 | | | | | | |
| Example | 69.996 | 515.0 | 0.93 | 0.04 | 554 | 12,875 |
| 19 | | | | | | |
| Example | 69.993 | 503.7 | 0.91 | 1.1 | 554 | 458 |
| 20 | | | | | | |
| Example | 69.988 | 515.0 | 0.93 | 0.64 | 554 | 805 |
| 21 | | | | | | |
| Example | 69.993 | 503.7 | 0.91 | 1.1 | 554 | 458 |
| 22 | | | | | | |
| Example | 55.988 | 2930.9 | 7.5 | 1.9 | 381 | 1,543 |
| 23 | | | | | | |
| Example | 55.988 | 2860.9 | 7.5 | 2.0 | 381 | 1,430 |
| 24 | | | | | | |

TABLE 2

| | Component (a) | Component (b) | Component (c) | | | | |
|---|---|---|---|---|---|---|---|
| | Hydrogen | Ammonium | | Average | | Component (d) | |
| | fluoride | fluoride | | molecular | Content | | Content |
| | (mass %) | (mass %) | Type | weight | (mass %) | Type | (mass %) |
| Comparative | 0.1 | 5.0 | Polystyrene | 75,000 | — | — | — |
| Example 1 | | | sulfonic | | | | |
| | | | acid | | | | |
| Comparative | 0.1 | 5.0 | Polystyrene | 75,000 | 0.002 | — | — |
| Example 2 | | | sulfonic | | | | |
| | | | acid | | | | |
| Comparative | 0.1 | 5.0 | Polystyrene | 75,000 | 0.002 | Polyoxyethylene | 0.01 |
| Example 3 | | | sulfonic | | | isodecyl | |
| | | | acid | | | ether | |
| Comparative | 1.0 | 10.0 | — | — | — | — | — |
| Example 4 | | | | | | | |
| Comparative | 1.0 | 10.0 | Polystyrene | 75,000 | 0.002 | — | — |
| Example 5 | | | sulfonic | | | | |
| | | | acid | | | | |
| Comparative | 1.0 | 10.0 | Polystyrene | 75,000 | 0.002 | Nonylamine | 0.01 |
| Example 6 | | | sulfonic | | | | |
| | | | acid | | | | |
| Comparative | 4.0 | 20.0 | — | — | — | — | — |
| Example 7 | | | | | | | |
| Comparative | 4.0 | 20.0 | Polystyrene | 75,000 | 0.002 | — | — |
| Example 8 | | | sulfonic | | | | |
| | | | acid | | | | |
| Comparative | 4.0 | 20.0 | Polystyrene | 75,000 | 0.002 | Decyl alcohol | 0.01 |
| Example 9 | | | sulfonic | | | | |
| | | | acid | | | | |
| Comparative | 7.0 | 23.0 | — | — | — | — | — |
| Example 10 | | | | | | | |
| Comparative | 7.0 | 23.0 | Polystyrene | 75,000 | 0.002 | — | — |
| Example 11 | | | sulfonic | | | | |
| | | | acid | | | | |
| Comparative | 7.0 | 23.0 | Polystyrene | 75,000 | 0.002 | Sodium | 0.01 |
| Example 12 | | | sulfonic | | | monododecyl | |
| | | | acid | | | phosphate | |
| Comparative | 25.0 | 19.0 | — | — | — | — | — |
| Example 13 | | | | | | | |
| Comparative | 25.0 | 19.0 | Polystyrene | 75,000 | 0.002 | — | — |
| Example 14 | | | sulfonic | | | | |
| | | | acid | | | | |
| Comparative | 25.0 | 19.0 | Polystyrene | 75,000 | 0.002 | Dodecyl alcohol | 0.01 |
| Example 15 | | | sulfonic | | | | |
| | | | acid | | | | |

| | | | | | Selectivity | Selectivity |
|---|---|---|---|---|---|---|
| | | | | | of etch | of etch |
| | | | | | rate | rate |
| | | Etch rate | | | (silicon | (silicon |
| | Component (e) | Silicon | Silicon | Cobalt | oxide | oxide |
| | Ultrapure | oxide | nitride | silicide | film/silicon | film/cobalt |
| | water | film | film | film | nitride | silicide |
| | (mass %) | (nm/min) | (nm/min) | (nm/min) | film) | film) |
| Comparative | 94.900 | 14.3 | 0.08 | 0.18 | 179 | 79 |
| Example 1 | | | | | | |
| Comparative | 94.898 | 14.1 | 0.04 | 0.17 | 353 | 83 |
| Example 2 | | | | | | |
| Comparative | 94.888 | 14.1 | 0.04 | 0.17 | 353 | 83 |
| Example 3 | | | | | | |
| Comparative | 89.000 | 109.2 | 0.38 | 1.3 | 287 | 84 |
| Example 4 | | | | | | |
| Comparative | 88.998 | 110.9 | 0.22 | 1.5 | 504 | 74 |
| Example 5 | | | | | | |
| Comparative | 88.988 | 110.7 | 0.22 | 1.2 | 503 | 92 |
| Example 6 | | | | | | |
| Comparative | 76.000 | 283.7 | 0.91 | 3.3 | 312 | 86 |
| Example 7 | | | | | | |
| Comparative | 75.998 | 284.0 | 0.64 | 2.9 | 444 | 98 |
| Example 8 | | | | | | |
| Comparative | 75.988 | 282.9 | 0.68 | 3.2 | 416 | 88 |
| Example 9 | | | | | | |
| Comparative | 70.000 | 510.7 | 1.39 | 5.3 | 367 | 96 |
| Example 10 | | | | | | |
| Comparative | 69.998 | 508.6 | 0.93 | 5.6 | 547 | 91 |
| Example 11 | | | | | | |
| Comparative | 69.988 | 492.2 | 0.91 | 5.0 | 541 | 98 |
| Example 12 | | | | | | |
| Comparative | 56.000 | 2910.6 | 7.5 | 29.6 | 388 | 98 |
| Example 13 | | | | | | |
| Comparative | 55.998 | 2881.2 | 5.6 | 30.0 | 515 | 96 |
| Example 14 | | | | | | |
| Comparative | 55.988 | 2915.4 | 5.6 | 31.5 | 521 | 93 |
| Example 15 | | | | | | |

As is clear from Tables 1 and 2, in the etching liquids according to Examples 1 to 3, the selectivity of the etch rate of the silicon oxide film to the silicon nitride film (silicon oxide film/silicon nitride film) and the selectivity of the etch rate of the silicon oxide film to the cobalt silicide film (silicon oxide film/cobalt silicide film) were both successfully improved as compared with the etching liquids according to Comparative Examples 1 to 3. In addition, in the etching liquids according to Examples 4 to 6, the selectivity of the etch rate of the silicon oxide film to the silicon nitride film and the selectivity of the etch rate of the silicon oxide film to the cobalt silicide film were both successfully improved as compared with the etching liquids according to Comparative Examples 4 to 6. In addition, in the etching liquids according to Examples 7 to 17, the selectivity of the etch rate of the silicon oxide film to the silicon nitride film and the selectivity of the etch rate of the silicon oxide film to the cobalt silicide film were both successfully improved as compared with the etching liquids according to Comparative Examples 7 to 9. Further, in the etching liquids according to Examples 18 to 22, the selectivity of the etch rate of the silicon oxide film to the silicon nitride film and the selectivity of the etch rate of the silicon oxide film to the cobalt silicide film were both successfully improved as compared with the etching liquids according to Comparative Examples 10 to 12. Further, in the etching liquids according to Examples 23 and 24, the selectivity of the etch rate of the silicon oxide film to the silicon nitride film and the selectivity of the etch rate of the silicon oxide film to the cobalt silicide film were both successfully improved as compared with the etching liquids according to Comparative Examples 13 to 15.

1. A micromachining processing agent used for micromachining of a laminated film including at least a silicon oxide film, a silicon nitride film, and a silicon alloy film, the micromachining processing agent comprising:
(a) hydrogen fluoride in an amount of 0.01 to 50 mass % with respect to a total mass of the micromachining processing agent;
(b) ammonium fluoride in an amount of 0.1 to 40 mass % with respect to a total mass of the micromachining processing agent;
(c) a water-soluble polymer in an amount of 0.001 to 10 mass % with respect to a total mass of the micromachining processing agent;
(d) an organic compound having a carboxyl group in an amount of 0.001 to 1 mass % with respect to a total mass of the micromachining processing agent; and
(e) water as an optional component,
wherein
the water-soluble polymer includes a polymer provided by polymerizing at least one monomer component selected from a group consisting of acrylic acid, ammonium acrylate, acrylamide, styrenesulfonic acid, ammonium styrenesulfonate, and styrenesulfonic acid ester, and
the silicon oxide film is selectively micromachined in the laminated film.

2. The micromachining processing agent according to claim 1, wherein the water-soluble polymer is polystyrene sulfonic acid.

3. The micromachining processing agent according to claim 1, wherein the organic compound having a carboxyl group is at least one selected from a group consisting of a carboxylic acid represented by CₙH₂ₙ₊₁COOH where n represents a natural number in a range of 0 to 9, a perfluoroalkyl carboxylic acid, a carboxylic acid having two or more carboxyl groups, and an amino acid.

4. The micromachining processing agent according to claim 3, wherein the carboxylic acid represented by CₙH₂ₙ₊₁COOH is hexanoic acid, heptanoic acid, octanoic acid, or nonanoic acid.

5. The micromachining processing agent according to claim 3, wherein the perfluoroalkyl carboxylic acid is perfluoropentanoic acid.

6. A micromachining processing method comprising, micromachining a laminated film including at least a silicon oxide film, a silicon nitride film, and a silicon alloy film, using a micromachining processing agent, wherein
the micromachining processing agent contains:
(a) hydrogen fluoride in an amount of 0.01 to 50 mass % with respect to a total mass of the micromachining processing agent;
(b) ammonium fluoride in an amount of 0.1 to 40 mass % with respect to a total mass of the micromachining processing agent;
(c) a water-soluble polymer in an amount of 0.001 to 10 mass % with respect to a total mass of the micromachining processing agent;
(d) an organic compound having a carboxyl group in an amount of 0.001 to 1 mass % with respect to a total mass of the micromachining processing agent; and
(e) water as an optional component,
the water-soluble polymer includes a polymer of at least one monomer component selected from a group consisting of acrylic acid, ammonium acrylate, acrylamide, styrenesulfonic acid, ammonium styrenesulfonate, and styrenesulfonic acid ester, and
the silicon oxide film is selectively micromachined in the laminated film.

7. The micromachining processing method according to claim 6, wherein the silicon oxide film is any one of a natural oxide film, a chemical oxide film, a silicon thermal oxide film, a non-doped silicate glass film, a phosphorus-doped silicate glass film, a boron-doped silicate glass film, a phosphorus boron-doped silicate glass film, a tetraethyl orthosilicate (TEOS) film, a fluorine-containing silicon oxide film, a carbon-containing silicon oxide film, a nitrogen-containing silicon oxide film, a spin on glass (SOG) film, or a spin on dielectric (SOD) film.

8. The micromachining processing method according to claim 6, wherein the silicon nitride film is any one of a silicon nitride film, an oxygen-containing silicon nitride film, or a carbon-containing silicon nitride film.

9. The micromachining processing method according claim 6, wherein the silicon alloy film is made of any one of cobalt silicide, nickel silicide, titanium silicide, or tungsten silicide.

10. The micromachining processing method according to claim 6, wherein the water-soluble polymer is polystyrene sulfonic acid.

11. The micromachining processing method according to claim 6, wherein the organic compound having a carboxyl group is at least one selected from a group consisting of a carboxylic acid represented by CₙH₂ₙ₊₁COOH where n represents a natural number in a range of 0 to 9, a perfluoroalkyl carboxylic acid, a carboxylic acid having two or more carboxyl groups, and an amino acid.

12. The micromachining processing method according to claim 8, wherein the carboxylic acid represented by CₙH₂ₙ₊₁COOH is hexanoic acid, heptanoic acid, octanoic acid, or nonanoic acid.

13. The micromachining processing method according to claim 8, wherein the perfluoroalkyl carboxylic acid is perfluoropentanoic acid.
